(19) United States
(12) Patent Application Publication
(10) Pub. No.: US 2012/0241867 A1
(43) Pub. Date: Sep. 27, 2012

(54) NON-VOLATILE SEMICONDUCTOR MEMORY DEVICE AND A MANUFACTURING METHOD THEREOF

(75) Inventors: Hitohisa ONO, Oita-ken (JP); Kazunori Nishikawa, Mie-ken (JP)

(73) Assignee: Kabushiki Kaisha Toshiba, Tokyo (JP)

(21) Appl. No.: 13/421,003

(22) Filed: Mar. 15, 2012

(30) Foreign Application Priority Data
Mar. 23, 2011 (JP) 2011-064704

(51) Int. Cl. H01L 27/088; H01L 21/762

(52) U.S. Cl. 257/368; 438/424; 257/E27.06; 257/E21.546

(57) ABSTRACT

In a non-volatile semiconductor memory device, first element isolation insulation layers in a memory cell area are formed by burying a first oxide film in first element isolation trenches of the memory cell area. The top surface of the first oxide film is positioned at a level between the top surface of a semiconductor substrate and the top surface of a first gate electrode. Each of second element isolation insulation layers in a peripheral area includes a first oxide film embedded in the entirety of second element isolation trenches of the peripheral area, and a second oxide film formed on the first oxide film. The top surface of the first oxide film is at a higher level than the top surface of the semiconductor substrate. The top surface of the second oxide film is at a higher level than the top surface of a first conductor film.

### CROSS REFERENCE TO RELATED APPLICATION

This application is based upon and claims the benefit of priority from prior Japanese Patent Application No. 2011-64704, filed on Mar. 23, 2011, the entire contents of which are incorporated herein by reference.

### BACKGROUND

1. Field

Embodiments of the invention relate to non-volatile semiconductor memory device and a manufacturing method thereof.

2. Description of the Related Art

Non-volatile semiconductor memory devices such as NAND-type flash memories are widely used, for example, in digital cameras, mobile terminals, portable audio devices, and portable personal computers using non-volatile semiconductor memory devices (SSDs) as mass data storages in place of hard disk drives.

Each of such non-volatile semiconductor memory devices has a memory cell area in which cell transistors are formed and a peripheral area in charge of controlling the data writing into and data reading out of memory cells. In general, the memory cell area and the peripheral area are different from each other in their structures and operational conditions such as an applied voltage.

The peripheral area includes plural transistors to which a high voltage is applied in order to drive cell transistors in the memory cell area. Each two adjacent of high voltage transistors are provided across an element isolation insulation layer.

A high field breakdown voltage has to be secured between each two adjacent high voltage transistors. A possible way of securing the high field breakdown voltage is to form deeper element isolation trenches between the high voltage transistors. However, if the deeper element isolation trenches are formed in element isolation areas and filled with a coating-type oxide film for element isolation such as polysilazane, a stress may increase and cause cracks and crystal defects. Thus, a sufficient breakdown voltage may not be secured between active areas of the high voltage transistors.

### BRIEF DESCRIPTION OF THE DRAWINGS

FIG. 1 is a schematic block diagram illustrating an embodiment.

FIG. 2A is a schematic diagram illustrating the planar layout pattern of a portion of a memory cell area.

FIG. 2B is a schematic diagram illustrating the planar layout pattern of a portion of a peripheral area.

FIG. 3A is a cross sectional view schematically illustrating a portion taken along the line 3A-3A of FIG. 2A.

FIG. 3B is a cross sectional view schematically illustrating a portion taken along the line 3B-3B of FIG. 2A.

FIG. 4A is a cross sectional view schematically illustrating a portion taken along the line 4A-4A of FIG. 2B.

FIG. 4B is a cross sectional view schematically illustrating a portion taken along the line 4B-4B of FIG. 2B.

FIGS. 5A, 5B, and 5C are cross sectional views schematically illustrating the portions corresponding respectively to FIG. 3A, FIG. 3B, and FIG. 4A at a step of manufacturing process.

FIGS. 6A, 6B, and 6C are cross sectional views schematically illustrating the portions corresponding respectively to FIG. 3A, FIG. 3B, and FIG. 4A at a step of manufacturing process.

FIGS. 7A, 7B, and 7C are cross sectional views schematically illustrating the portions corresponding respectively to FIG. 3A, FIG. 3B, and FIG. 4A at a step of manufacturing process.

FIGS. 8A, 8B, and 8C are cross sectional views schematically illustrating the portions corresponding respectively to FIG. 3A, FIG. 3B, and FIG. 4A at a step of manufacturing process.

FIGS. 9A, 9B, and 9C are cross sectional views schematically illustrating the portions corresponding respectively to FIG. 3A, FIG. 3B, and FIG. 4A at a step of manufacturing process.

FIGS. 10A, 10B, and 10C are cross sectional views schematically illustrating the portions corresponding respectively to FIG. 3A, FIG. 3B, and FIG. 4A at a step of manufacturing process.

FIGS. 11A, 11B, and 11C are cross sectional views schematically illustrating the portions corresponding respectively to FIG. 3A, FIG. 3B, and FIG. 4A at a step of manufacturing process.

FIGS. 12A, 12B, and 12C are cross sectional views schematically illustrating the portions corresponding respectively to FIG. 3A, FIG. 3B, and FIG. 4A at a step of manufacturing process.

FIGS. 13A, 13B, and 13C are cross sectional views schematically illustrating the portions corresponding respectively to FIG. 3A, FIG. 3B, and FIG. 4A at a step of manufacturing process.

FIGS. 14A, 14B, and 14C are cross sectional views schematically illustrating the portions corresponding respectively to FIG. 3A, FIG. 3B, and FIG. 4A at a step of manufacturing process.

FIGS. 15A, 15B, and 15C are cross sectional views schematically illustrating the portions corresponding respectively to FIG. 3A, FIG. 3B, and FIG. 4A at a step of manufacturing process.

FIGS. 16A, 16B, and 16C are cross sectional views schematically illustrating the portions corresponding respectively to FIG. 3A, FIG. 3B, and FIG. 4A at a step of manufacturing process.

FIGS. 17A, 17B, and 17C are cross sectional views schematically illustrating the portions corresponding respectively to FIG. 3A, FIG. 3B, and FIG. 4A at a step of manufacturing process.

FIGS. 18A, 18B, and 18C are cross sectional views schematically illustrating the portions corresponding respectively to FIG. 3A, FIG. 3B, and FIG. 4A at a step of manufacturing process.

FIGS. 19A, 19B, and 19C are cross sectional views schematically illustrating the portions corresponding respectively to FIG. 3A, FIG. 3B, and FIG. 4A at a step of manufacturing process.

### DETAILED DESCRIPTION

A non-volatile semiconductor memory device according to an embodiment includes a memory cell area where cell transistors and first element isolation insulation layers are provided, and also includes a peripheral area where high voltage transistors and second element isolation insulation layers are provided. Each of the cell transistors includes a first gate electrode formed over a semiconductor substrate with a first gate insulator film formed in between, and also includes a second gate electrode formed over the first gate electrode with an inter-gate insulator film formed in between. The first element isolation insulation layers are each embedded in a first element isolation trench in a way to electrically isolate the cell transistors from one another, the first element isolation trench isolating the cell transistors from each other.

Each of the high voltage transistors includes a third gate electrode that includes a first conductor film and a second conductor film. The first conductor film is formed over the semiconductor substrate with a second gate insulator film formed in between. The second conductor film is formed over the first conductor film and is in contact with the first conductor film via an opening formed in the inter-gate insulator film.

The second element isolation insulation layers are each embedded in a second element isolation trench in a way to electrically isolate the high voltage transistors from each other, the second element isolation trench isolating the high voltage transistors from each other. The first element isolation insulation layer in the memory cell area is formed by burying a first oxide film in the first element isolation trench in the memory cell area, and the first oxide film has a top surface positioned at a level between a top surface of the semiconductor substrate and a top surface of the first gate electrode.

The second element isolation insulation layer in the peripheral area is embedded in entirety of the second element isolation trench in the peripheral area, and includes a first oxide film and a second oxide film. The first oxide film is embedded has a top surface positioned at a higher level than the top surface of the semiconductor substrate. The second oxide film has a top surface positioned at a higher level than a top surface of the first conductor film.

A manufacturing method of a non-volatile semiconductor memory device according to an embodiment includes the steps of: forming a first conductor film for a floating gate electrode in a memory cell area of a semiconductor substrate with a first gate insulator film formed in between, and forming the first conductor film in a peripheral area of the semiconductor substrate with a second gate insulator film formed in between; forming element isolation trenches in the first conductor film, the first gate insulator film, the second gate insulator film, and an upper portion of the semiconductor substrate; forming a first oxide film in each of the element isolation trenches; forming an inter-gate insulator film on the first oxide film and the first conductor film in the memory cell area and in the peripheral area; and forming a second conductor film for a control gate electrode on the inter-gate insulator film.

In addition, the method also includes the steps of: in the peripheral area, forming opening grooves in the second conductor film, the inter-gate insulator film, and the first conductor film, and removing the second conductor film, the inter-gate insulator film, and a part of the first conductor film formed on top of the first oxide film; forming a second oxide film in a region of the peripheral area where the second conductor film is removed; removing the second oxide film formed on internal surfaces of an opening region of the inter-gate insulator film in the peripheral area; and forming a third conductor film through the opening region of the inter-gate insulator film in the peripheral area, and thereby electrically connecting the first conductor film and the second conductor film to each other.

A case where the invention is applied to a NAND-type flash memory device will be described below as an embodiment by referring to the drawings. In the description of the drawings below, the same or similar portions are denoted by the same or similar reference numeral. Note that the drawings are schematic, so the relationship between the thickness and planar dimensions, and the ratios among the thicknesses of the layers may differ from actual ones.

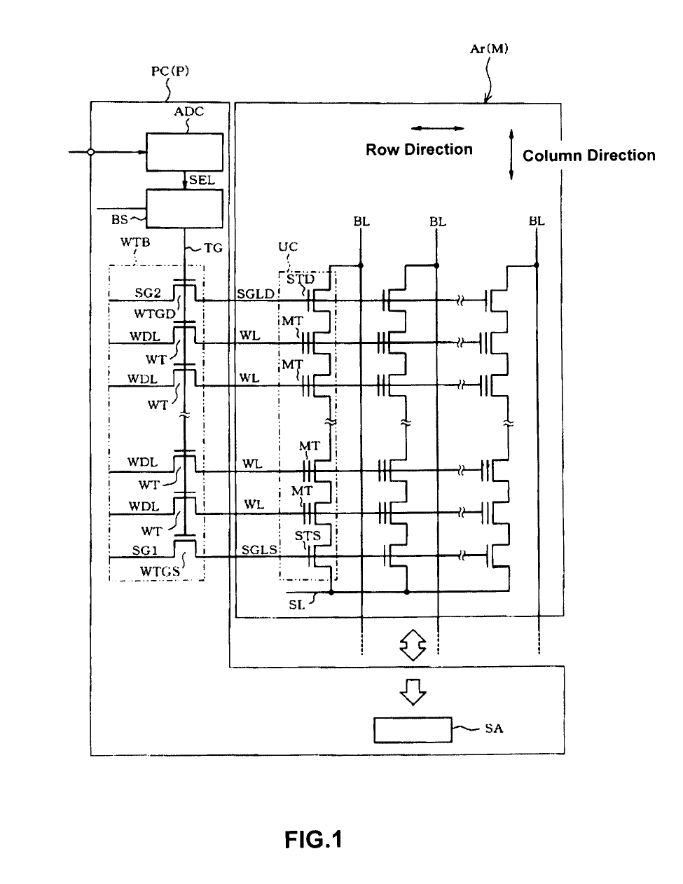

FIG. 1 is a block diagram schematically illustrating the electrical configuration of the NAND-type flash memory device. As shown in FIG. 1, a NAND-type flash memory device 1 includes a memory cell array Ar and a peripheral circuit PC. The memory cell array Ar includes multiple memory cells arranged in a matrix shape. The peripheral circuit PC is in charge of reading out data from, writing data into, and erasing data from each of the memory cells of the memory cell array Ar. In addition, the NAND-type flash memory device 1 includes an unillustrated input/output interface circuit. Note that the memory cell array Ar is formed in a memory cell area M whereas the peripheral circuit PC is formed in a peripheral area P.

The memory cell array Ar formed in the memory cell area M includes multiple cell units UC. Each of the cell units UC includes a select gate transistor STD connected to a bit line BL, a select gate transistor STS connected to a source line SL, and plural cell transistors MT connected in series to one another between the above-mentioned two select gate transistors STD and STS. Any number of cell transistors MT may be connected in series to one another. In terms of data lengths, the number of cell transistors MT connected in series is obtained by adding one to four dummy memory cell transistors to 2 power k of cell transistors MT (e.g., 64 (=m)) where k is a positive integer.

A single block is formed with n columns of the cell units UC arranged in the row direction (in the right-and-left direction in FIG. 1). The memory cell array Ar includes plural blocks of cell units UC arranged in the column direction (in the up-and-down direction in FIG. 1). Note that for the sake of simpler explanation, FIG. 1 shows only one block.

The peripheral circuit PC formed in the peripheral area P is disposed in a surrounding area of the memory cell array Ar formed in the memory cell area M. The peripheral circuit PC includes, among other things, an address decoder ADC, a sense amplifier SA, a booster circuit BS including a charge pump, and a transfer transistor portion WTB. The address decoder ADC is connected to the transfer transistor portion WTB via the booster circuit BS.

If the address decoder ADC receives an address signal from outside, the address decoder ADC outputs a selection signal SEL to select a corresponding block. The booster circuit BS is supplied with a drive voltage from outside. The booster circuit BS steps up the supplied voltage and then provides a gate voltage thus produced to transfer gate transistors WTGD, WTGS, and WT via a transfer gate line TG.

The transfer transistor portion WTB includes the transfer gate transistor WTGD, the transfer gate transistor WTGS, and the word line transfer gate transistors WT. The transfer gate transistor WTGD corresponds to the select gate transistor STD. The transfer gate transistor WTGS corresponds to the select gate transistor STS. The word line transfer gate transistors WT correspond respectively to the cell transistors MT.

One of the drain and the source of the transfer gate transistor WTGD is connected to a select gate driver line SG2, while the other one is connected to a select gate line SGLD. One of the drain and the source of the transfer gate transistor WTGS is connected to a select gate driver line SG1, while the other one is connected to a select gate line SGLS. One of the drain and the source of each of the word line transfer gate transistors WT is connected to the corresponding one of word-line drive signal lines WDL, while the other one is connected to the corresponding one of word lines WL provided in the memory cell array Ar (memory cell area M).

The select gate transistors STD in the plural cell units UC arranged in the row direction have the gate electrodes commonly connected to each other through the select gate line SGLD. Likewise, the select gate transistors STS in the plural cell units UC arranged in the row direction have the gate electrodes commonly connected to each other through the select gate line SGLS. The sources of the select gate transistors STS are commonly connected to a source line SL.

The cell transistors MT in the plural cell units UC arranged in the row direction are commonly connected to each other through the word lines WL. The transfer gate transistors WTGD, WTGS, and WT have the gate electrodes commonly connected to each other and connected to booster circuit BS through the transfer gate line TG. The sense amplifier SA is connected to the bit lines BL, and is connected also to a latch circuit where, when data are read out from the memory cells, the readout data are temporarily stored.

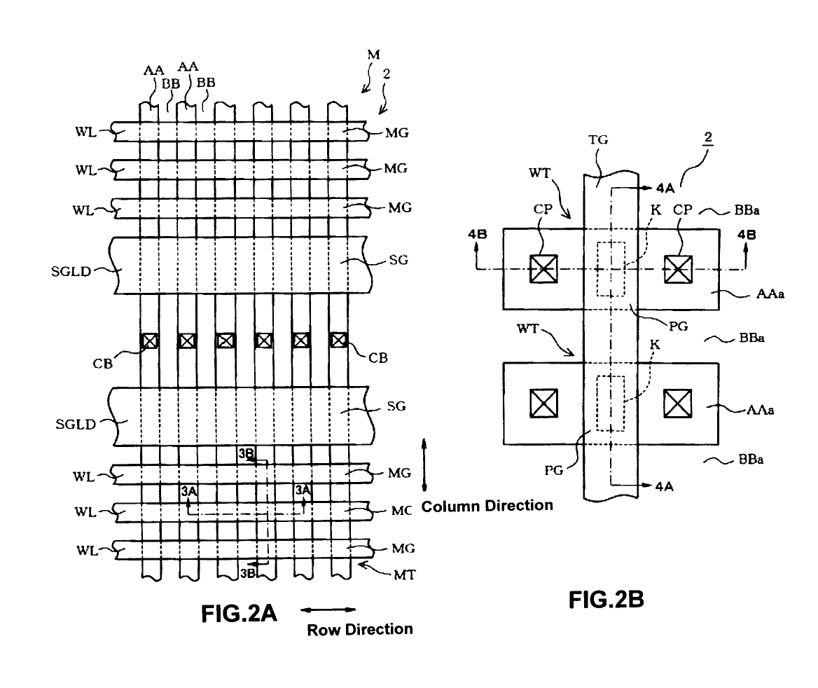

Next, a planar layout pattern of the electrical configuration described above will be described by referring to FIGS. 2A and 2B. FIG. 2A is a plan view illustrating a layout pattern of a portion of the memory cell area, the portion including the select gate transistor STD of one block and the select gate transistor STD of the adjacent block.

On a semiconductor substrate (e.g., a silicon substrate) 2, plural element isolation areas BB each having a shallow trench isolation (STI) structure extending in the column direction in FIG. 2A to isolate elements from one another are arranged in the column direction. In the row direction, these element isolation areas BB are arranged at predetermined intervals, and thereby formed are active areas AA that are separated from one another. Plural word lines WL each of which connects the gate electrodes MG of the respective cell transistors MT to each other are extending in the row direction in FIG. 2A so that each word line WL intersects orthogonally the active areas AA. The select gate lines SGLD of the select gate transistor STD are formed in the row direction in FIG. 2 at positions that are adjacent to the corresponding word lines WL.

Bit line contacts CB are formed respectively on active areas AA that are located between the pair of select gate lines SGLD. Gate electrodes MG of the cell transistors MT are each formed on the active area AA at a portion intersecting with the word line WL. Gate electrodes SG of the select gate transistors STD are each formed on the active area AA at a portion intersecting with the select gate lines SGLD.

FIG. 2B is a plan view illustrating the layout pattern of a portion of the high voltage transistors in the peripheral area. The transistors formed in the peripheral area P include high voltage transistors driven by the transfer gate transistors WTGD, WTGS, and WT with a high voltage (e.g., 20 V) described in the description of the configuration shown in FIG. 1 as well as unillustrated low voltage transistors driven with low voltages (several voltages). Though not illustrated in FIG. 2B, some other circuit elements, such as capacitive elements and resistive elements, are also formed in the peripheral area P. FIG. 2B shows the transfer gate transistors WT as examples of the high voltage transistors.

In each transfer gate transistor WT, element isolation areas BBa, each having a STI structure formed on the semiconductor substrate 2, are formed to surround each of the rectangular-shaped active areas AAa. The element isolation areas BBa are formed to isolate the active area AAa of one transfer gate transistor WT from the active area AAa of the other transfer gate transistor WT. The gate electrodes PG serving as the transfer gate line TG are formed to pass over the active areas AAa to bridge the element isolation areas BBa located at the edge portions.

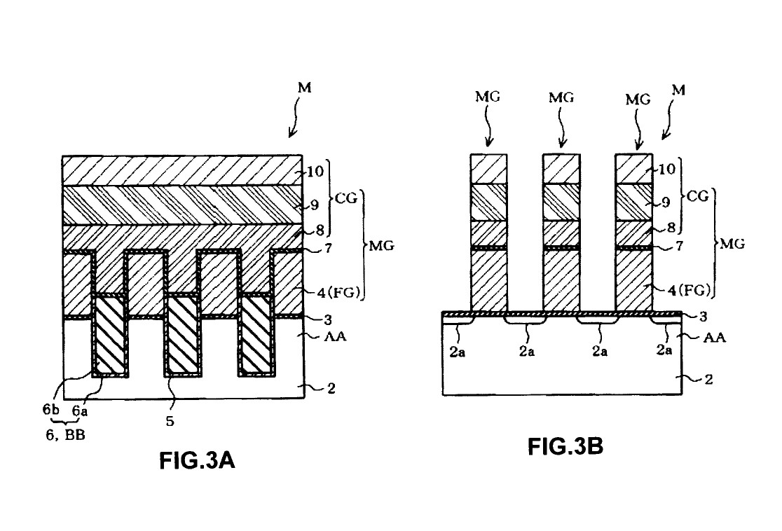

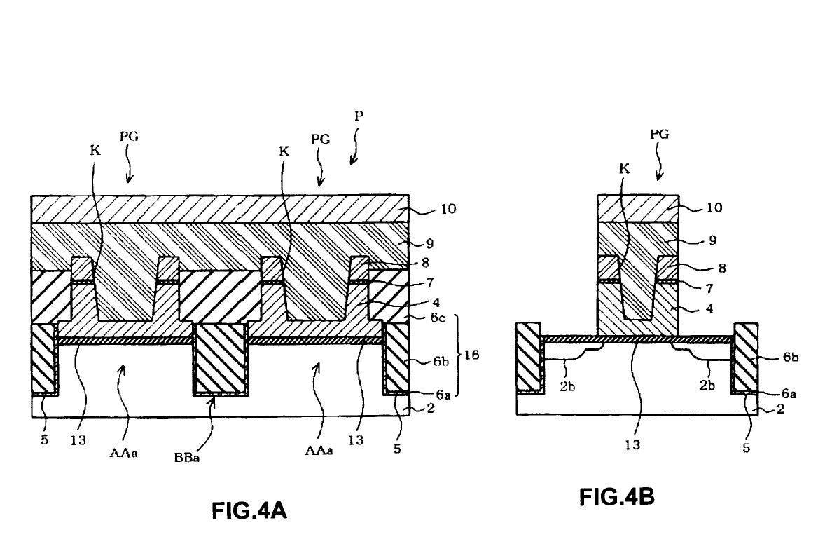

FIGS. 3A and 3B are schematic cross sectional views illustrating respectively the section taken along the line 3A-3A of FIG. 2A and the section taken along the line 3B-3B of FIG. 2A. FIG. 3A is a cross sectional view taken along one of the word lines WL of the cell transistors in the memory cell area M in such a manner as to cut across several active areas AAa. FIG. 3B shows a section taken along one of the active areas AA in the memory cell area M in such a manner as to cut across the gate electrodes MG of several cell transistors MT. FIGS. 4A and 4B are schematic side elevation views illustrating respectively the section taken along the line 4A-4A of FIG. 2B and the section taken along the line 4B-4B of FIG. 2B. FIG. 4A shows a section cutting across the active areas AAa of several transfer gate transistors WT. FIG. 4B shows a section cutting across the gate electrode PG of the transfer gate transistors WT.

Note that the bit line contacts CB shown in FIG. 2A are not depicted in the sectional views of FIGS. 3A and 3B. The peripheral contacts CP formed in the active areas AAa in FIG. 2B are not depicted in the sectional views of FIGS. 4A and 4B.

FIGS. 3A and 3B illustrates the overall configuration of the memory cell area M. In an upper layer portion of the semiconductor substrate 2, element isolation trenches 5 are formed as first element isolation trenches. Element isolation insulation layers 6 are embedded in the element isolation trench 5, and thereby element isolation areas BB are formed.

Thus, the active areas AA isolated from each other by the element isolation areas BB are formed in the upper layer portion of the semiconductor substrate 2. Each of the element isolation insulation layers 6 is formed in a stack structure in which a coat-type oxide film 6b (a first oxide film: for example, polysilazane) is embedded inside an oxide film 6a serving as a third oxide film which is formed of a high temperature oxide (HTO) film and is formed along the internal surface of the element isolation trench 5. The element isolation insulation layers 6 are embedded to reach a predetermined depth of the semiconductor substrate 2 and stick out upwards from the level of the top surface of the semiconductor substrate 2.

A gate insulation film 3 is formed on the top surfaces of the active areas AA. On the top surface of the gate insulation film 3, gate electrodes MG of the cell transistors MT are formed. The gate electrodes MG are formed over the semiconductor substrate 2, and arranged in the column direction at predetermined intervals. In an upper layer portion of the semiconductor substrate 2, impurity-diffused regions 2a, which correspond to the source/drain regions, are formed between every two adjacent gate electrodes MG.

Each of the gate electrodes MG has a layered structure including plural films and is formed by stacking on top of the upper surface of the gate insulation film 3, a conductive film 4 serving as the first gate electrode, an inter-gate insulator film 7, a conductive film 8 serving as the second gate electrode, a conductive film 9, and a conductive film 10 in this sequence. In the memory cell area M, the conductive film 4 serves as a floating gate electrode FG. The conductive films 8, 9, and 10, together forming a second conductor film, serve as a control gate electrode CG.

The conductive film 4 is a conductive film such as a polycrystalline silicon film or amorphous silicon film. The inter-gate insulator film 7 is made, for example, of an oxide-nitride-oxide (ONO) film or a nitride-oxide-nitride-oxide-nitride (NONON) film. Each of the conductive films 8 and 9 is a conductive film made such as a polycrystalline silicon film or amorphous silicon film. The conductive film 10 is a silicide layer made by silicidation with metal such as nickel (Ni) and cobalt (Co). The control gate electrode CG (i.e., conductive films 8, 9, and 10) is formed to face the upper surface and the upper side surfaces of each floating gate electrode FG (i.e., the conductive film 4).

Each element isolation insulation layer 6 is formed to have the top surface positioned below the top surface of the conductive film 4 but above the bottom surface of the conductive film 4. The inter-gate insulator film 7 is formed along the top surfaces of the element isolation insulation layers 6, the upper side surfaces of each conductive film 4, and the top surface of each conductive film 4. The conductive film 8 is formed on the top surface of the inter-gate insulator film 7 right above the element isolation insulation layers 6.

Though not illustrated in FIG. 3B, an interlayer insulation film such as a tetraethyl orthosilicate (TEOS) oxide film is formed by being embedded in the space between every two adjacent gate electrodes MG.

Next, description will be given below of the structure of a gate electrode PG (shown in FIGS. 4A and 4B) of the transfer gate transistor WT provided in the peripheral area P. In the peripheral area P, the element isolation trench 5 (corresponding to the second element isolation trenches) are formed in an upper layer portion of the semiconductor substrate 2.

Second element isolation insulation layers 16 are embedded in the element isolation trenches 5 formed in the semiconductor substrate 2 within the peripheral area P, and thereby the element isolation areas BBa are formed. In the peripheral area P, the upper layer portion of the semiconductor substrate 2 are divided into island-like segments by the element isolation areas BBa, and thereby the active areas AAa are formed. The lower portion of each second element isolation insulation layer 16 formed in the peripheral area P has a layered structure including an oxide film (HTO film) 6a and another oxide film 6b, which is similar to that of the isolation insulation layer 6 formed in the memory cell area M. In addition, an oxide film 6c is formed on top of the oxide film 6b. Note that, although no oxide film 6c is formed on the oxide film 6b in the section illustrated in FIG. 4B, the oxide film 6c may be formed thereon.

The top surfaces of the oxide films 6a and 6b of the second element isolation insulation layer 16 are at a higher level than the top surface of the semiconductor substrate 2. The top surface of the second element isolation insulation layer 16 is below the top surface of the first conductor film 4 and above the bottom surface of the first conductor film 4. The oxide film 6c is positioned at a side of the conductive film 4, inter-gate insulator film 7, and conductive film 8, and is formed on the oxide films 6b and 6a. The top surface of each oxide film 6c is below the top surface of the conductive film 8 and above the bottom surface of the conductive film 8. The oxide film 6b has a larger stress than the oxide film 6c. Hence, the oxide film 6c is made of a film that is less likely to have crystal defects compared with that of which the oxide film 6b is made.

On the top surface of the active area AAa of the transfer gate transistor WT, a second gate insulator film 13 is formed in place of the first gate insulator film 3 formed in the memory cell area M. The gate insulation film 13 is thinner than the gate insulation film 3 formed in the memory cell area M.

A conductive film 4 is formed on the top surface of the gate insulation film 13, and the inter-gate insulator film 7 is formed on the top surface of the conductive film 4. The conductive film 8 is formed on the top surface of the inter-gate insulator film 7. As shown in FIG. 4A, a side portion of the conductive film 8, a side portion of the inter-gate insulator film 7, and an upper end portion of the conductive film 4 form a structure where parts of these portions are cut away from a lower side surface of the conductive film 4 towards the center of the conductive film 4. In addition, an opening groove K is defined by a central portion of the upper portion of the conductive film 8, the inter-gate insulator film 7 and the conductive film 4. The conductive film 9 is embedded in the opening grooves K. Note that as shown in FIG. 2B, each opening groove K is formed to extend in the direction in which each gate electrode PG extends.

The structural contact of the conductive films 4, 8, and 9 substantially allows the electrical connection among these films. The conductive film 10 is formed on the top surface of the conductive film 9. Thus, the gate electrode PG, which includes the conductive film 4, the inter-gate insulator film 7, and the conductive film 8, 9, and 10, of the transfer gate transistor WT is formed over the semiconductor substrate 2 with the gate insulation film 13 formed in between.

As shown in FIG. 4B, the impurity-diffused regions 2b with a lightly doped drain (LDD) structure are formed to serve as source/drain regions. The impurity-diffused regions 2b and the gate electrode PG together form the transfer gate transistor WT.

Though not illustrated in FIGS. 3A and 3B, not only the gate electrodes MG but also the select gate transistors STD and STS shown in FIG. 1 are formed in the memory cell area M. Like the gate electrodes PG, the select gate electrodes of the select gate transistors STD and STS allow the electrical connection between the conductive film 4 and the conductive film 9 in a state where the opening grooves K are formed in the inter-gate insulator film 7.

The semiconductor structure described above is one that is still in the course of the manufacturing process. In addition to the configuration described above, the bit line contacts CB, source line contacts, a multilayer wiring structure formed in the upper layer of the above-described configuration, and various circuit structures in the peripheral area P are formed and thus, the NAND-type flash memory device 1 is completed.

In summary, the NAND-type flash memory device of the embodiment has the following characteristic structure. The NAND-type flash memory device 1 includes the memory cell area M provided with the cell transistors MT and the first element isolation insulation layers 6 and the peripheral area P provided with the transfer gate transistors WT and the second element isolation insulation layers 16. Each cell transistor MT includes the floating gate electrode FG formed over the semiconductor substrate 2 with the gate insulation film 3 formed in between and the control gate electrode CG formed over the floating gate electrode FG with the inter-gate insulator film 7 formed in between.

The first element isolation insulation layers 6 are embedded in the element isolation trenches 5 that isolate the cell transistors MT from one another, and thereby electrically isolate the cell transistors MT from one another. The transfer gate transistor WT includes the gate electrode PG, which includes the conductive film 4 and the conductive film 9. The conductive film 4 is formed over the semiconductor substrate 2 with the gate insulation film 3 formed in between. The conductive film 9 is formed above the conductive film 4 so that the conductive film 9 is in contact with the conductive film 4 via the opening groove K formed in the inter-gate insulator film 7.

The second element isolation insulation layers 16 electrically isolate the transfer gate transistors WT from one another with the oxide film 6a and 6b embedded in the second element isolation trenches 5 that isolate the transfer gate transistors WT from one another. The first element isolation insulation layers 6 in the memory cell area M are formed by burying the oxide films 6a and 6b in the first element isolation trenches 5 in the memory cell area M. The top surface of the element isolation insulation layer 6 is at a higher level than the top surface of the semiconductor substrate 2. With the oxide films 6a and 6b, the top surface of the element isolation insulation layer 6 is at a lower level than the top surface of the floating gate electrode FG.

The second element isolation insulation layers 16 in the peripheral area P are formed by burying the oxide film 6b almost entirely in the element isolation trenches 5 in the peripheral area P. The top surface of the second element isolation insulation layer 16 is at a higher level than the top surface of the semiconductor substrate 2. The top surface of the oxide film 6c of the second element isolation insulation layer 16 is at a higher level the top surface of the conductive film 4. Hence, the second element isolation insulation layer 16 is formed with a large thickness. Accordingly, an improvement in the breakdown voltage between the active areas AAa of the transfer gate transistors WT can be achieved.

The oxide film 6b is made of polysilazane, which tends to increase the stress of the element isolation area BBa. The oxide film 6c that is deposited on the oxide film 6b by plasma CVD allows the formation of the second element isolation insulation layer 16 in the peripheral area P while lowering the above-mentioned stress. Hence, the element isolation areas BBa with desirable characteristics can be formed.

The oxide films 6c are formed only on the oxide films 6b in the peripheral area P. Thus, the oxide films 6c are formed on the first oxide films 6b of the element isolation trenches 5 in the peripheral area P without being formed in the memory cell area M. Thus, the characteristics of the elements in the memory cell area M are not adversely affected. The oxide films 6a are formed below the oxide films 6b and along the internal surfaces of the element isolation trenches 5.

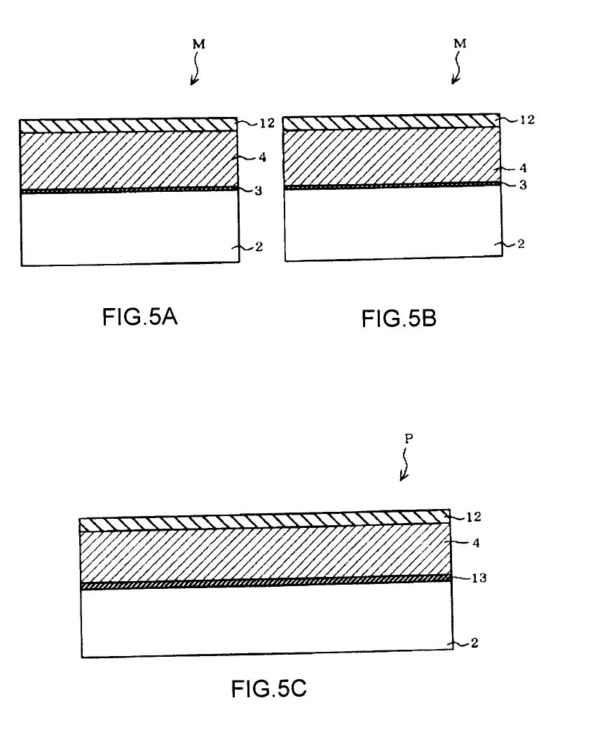

A manufacturing method of the NAND-type flash memory device with the above-described configuration will be described below by referring to FIGS. 5A, 5B, and 5C to 19A, 19B, and 19C. The following description of this embodiment focuses mainly on the characteristic portions, but addition of another or some other extra steps is allowable as long as the extra steps are commonly-practiced ones. In addition, an unnecessary step may be omitted. Furthermore, the order of the steps to be described below may be changed if necessary and if such re-ordering is practically possible.

Parts A of FIGS. 5 to 19 (i.e., FIG. 5A to 19A) schematically illustrate cross sectional structures corresponding to FIG. 3A at different manufacturing steps. Parts B of FIGS. 5 to 19 (i.e., FIG. 5B to 19B) schematically illustrate cross sectional structures corresponding to FIG. 3B at different manufacturing steps. Parts C of FIGS. 5 to (i.e., FIG. 5C to 19C) schematically illustrate vertically-cut sectional structures corresponding to FIG. 4A at different manufacturing steps.

As shown in FIGS. 5A to 5C, a second gate insulator film 13 made of a silicon oxide film is formed in a peripheral area P on the top surface of a semiconductor substrate 2, and then a first gate insulator film 3 made of a silicon oxide film is formed in a memory cell area M on the top surface of the semiconductor substrate 2. The second gate insulator film 13 is formed to be thicker than the first gate insulator film 3.

Subsequently, either amorphous silicon, or polycrystalline silicon, doped with impurities is deposited, as a conductive film 4 (corresponding to a first conductor film) having a predetermined thickness, on the gate insulation film 3 by the low pressure chemical vapor deposition (LP-CVD). Then, a silicon nitride film 12 as a mask for processing is formed on the top surface of the conductive film 4.

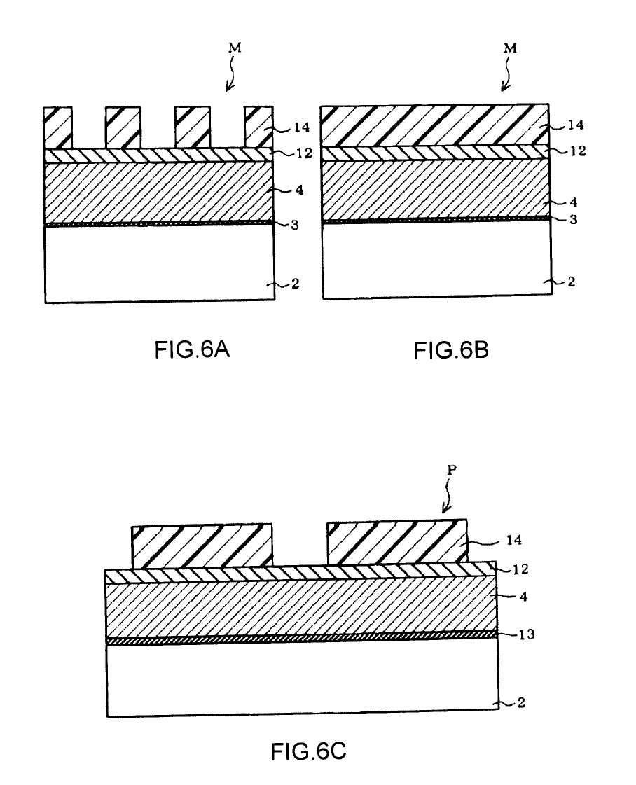

Subsequently, as shown in FIGS. 6A to 6C, photoresist 14 is applied to the top surface of the silicon nitride film 12, and then the applied photoresist 14 is patterned by the photolithography.

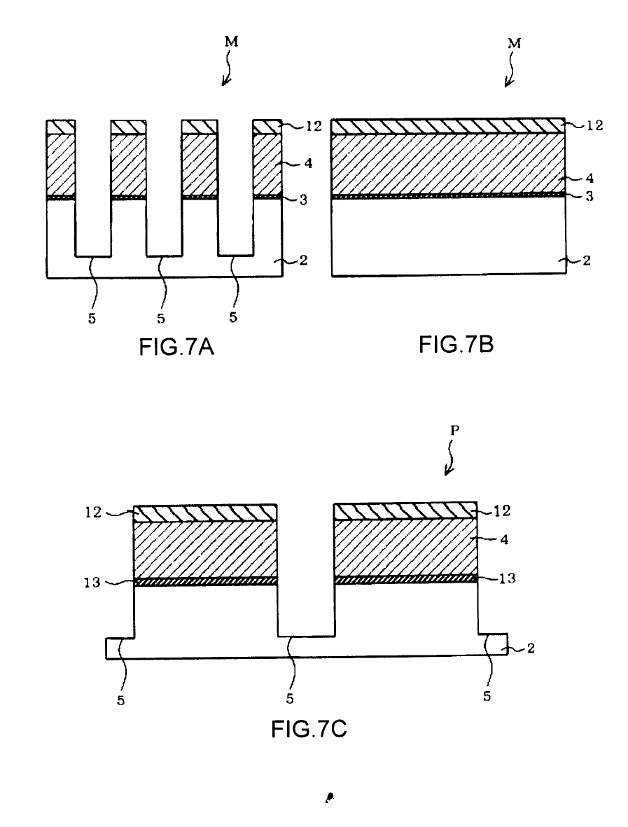

Subsequently, as shown in FIGS. 7A to 7C, an anisotropic etching process by RIE (Reactive Ion Etching) technique, for example, is performed to remove some parts of the silicon nitride film 12, the conductive film 4, the gate insulation film 3, and an upper layer portion of the semiconductor substrate 2. Thus, element isolation trenches 5 are formed. In this step, element isolation trenches 5 are formed in the memory cell area M along the direction orthogonal to the plane of FIGS. 6A and 6B, and thereby active areas AA are defined. In the peripheral area P, island-shaped active areas AAa are formed in an upper layer portion of the semiconductor substrate 2. Note that, as shown in FIGS. 7A and 7C, both the element isolation trenches 5 (i.e., first element isolation trenches) in the memory cell area M and the element isolation trenches 5 (i.e., second element isolation trenches) in the peripheral area P are formed simultaneously.

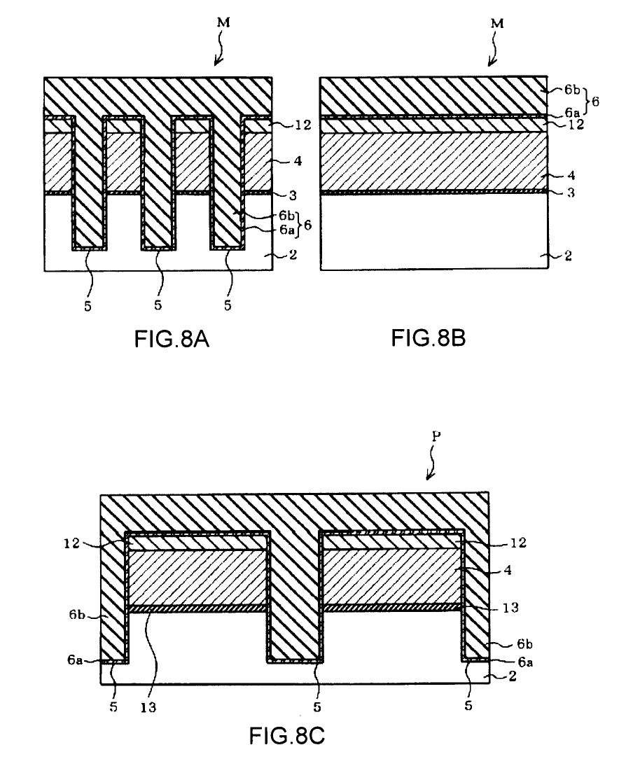

Subsequently, as shown in FIGS. 8A to 8C, oxide films 6a and 6b are formed in this order to bury entirely the element isolation trenches 5 both in the memory cell area M and in the peripheral area P. Specifically, the oxide film 6a is formed first as an HTO film by the LP-CVD. The oxide film 6a formed at this time is formed along the internal surfaces of the element isolation trenches 5 both in the memory cell area M and in the peripheral area P, and is also formed along the side surfaces of the gate insulation films 3 and 13, the side surfaces of the first conductor films 4, and the side surfaces and the top surfaces of silicon nitride films 12.

Then, the oxide film 6b (coating film, SOG (spin on glass)) to be a coating-type isolation film is formed on the oxide film 6a. The oxide film 6b is formed firstly by preparing a polymer solution by solving, for example, overhydrogenated silazane polymer in an organic solvent, then by applying the polymer solution uniformly on the surface of the semiconductor substrate 2, and then the impurities are removed from the polymer solution to transform the applied solution to a silicon oxide film. Hereinafter, the coating-type oxide film formed by the above-described technique will be referred to as polysilazane.

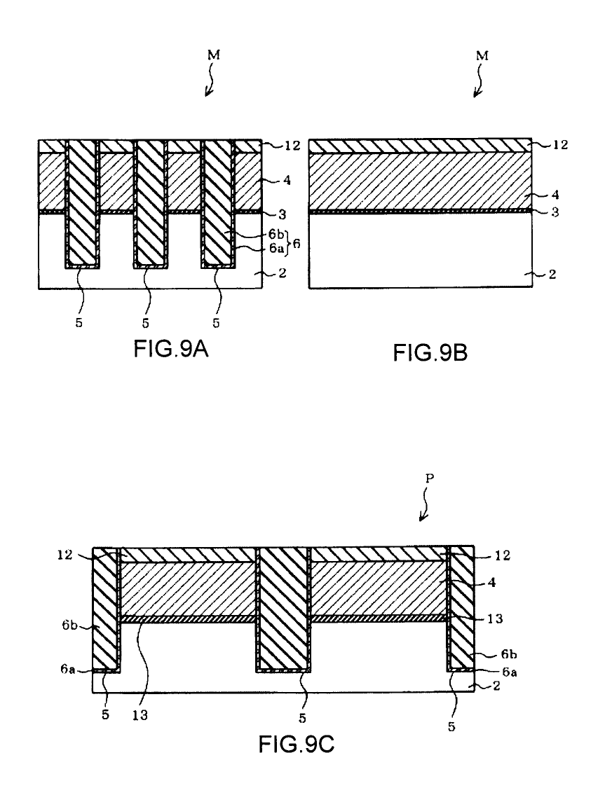

Subsequently, as shown in FIGS. 9A to 9C, the oxide films 6a and 6b are planarized by the chemical mechanical polishing (CMP) so that the top surfaces of the flattened oxide films 6a and 6b can be positioned at the same level as the level of the top surface of the silicon nitride film 12.

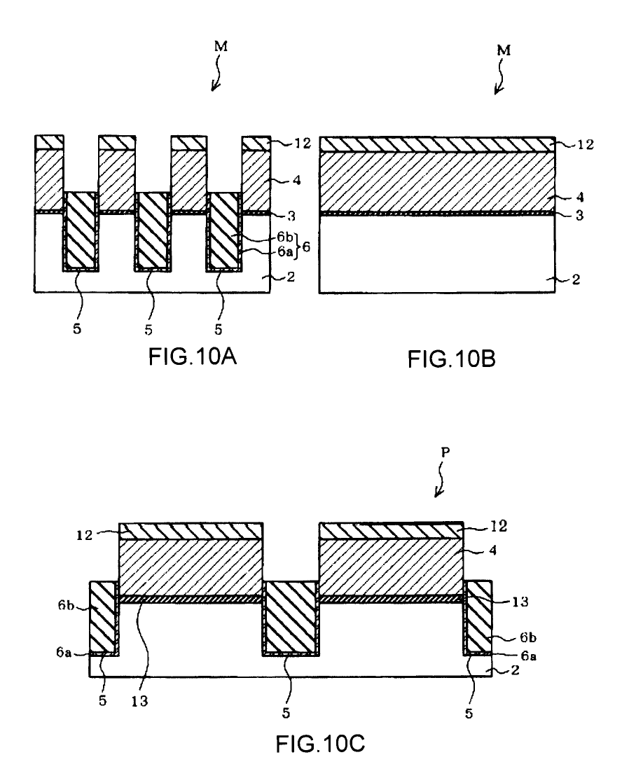

Subsequently, as shown in FIGS. 10A to 10C, either a RIE process or a wet etching process is performed on the oxide films 6a and 6b. Thus the top surfaces of the oxide films 6a and 6b in the memory cell area M are etched back to adjust the levels of the top surfaces of the oxide films 6a and 6b to desired levels.

As described earlier, the control gate electrodes CG (conductive films 8, 9, and 10) are formed to face the floating gate electrodes FG (conductive film 4). The above-described etching process is performed to enlarge the facing area of the floating gate electrode FG and the facing area of the control gate electrode CG. Also in the peripheral area P, similar etching process is performed to etch the upper portions of the oxide films 6a and 6b.

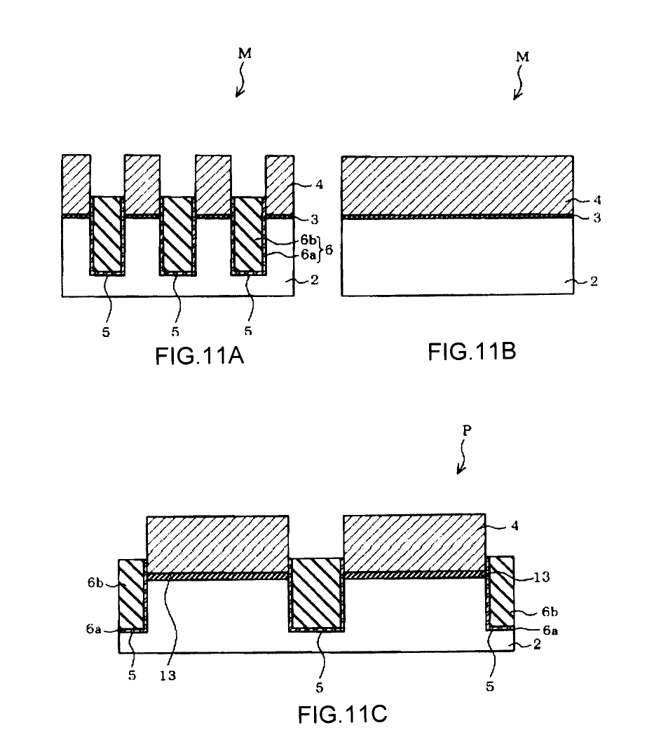

Subsequently, as shown in FIGS. 11A to 11C, a wet etching process is performed with phosphoric acid to remove the silicon nitride film 12.

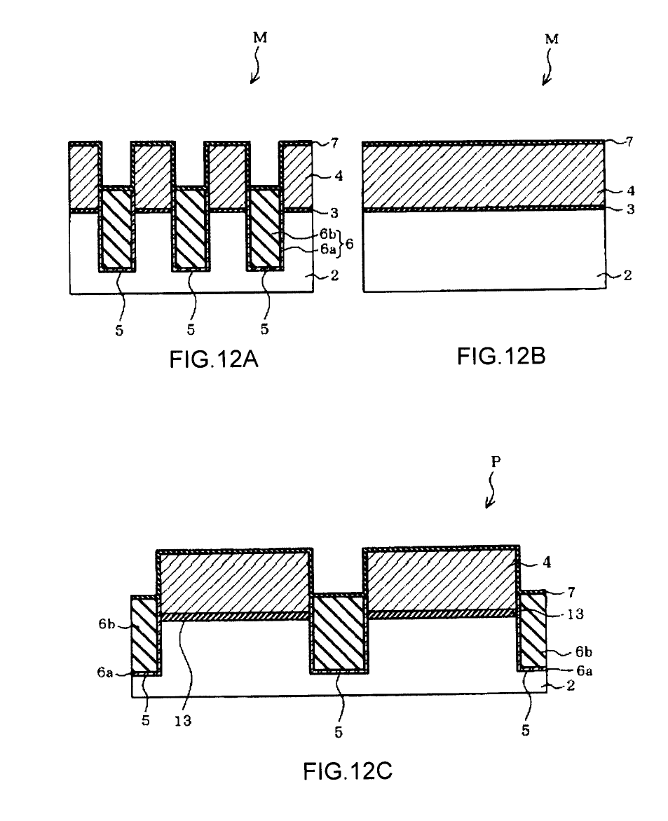

Subsequently, as shown in FIGS. 12A to 12C, an ONO film is formed as an inter-gate insulator film 7 by the LP-CVD. Note that radical nitridation processes may be performed before and after the formation of the ONO film to form a NONON film.

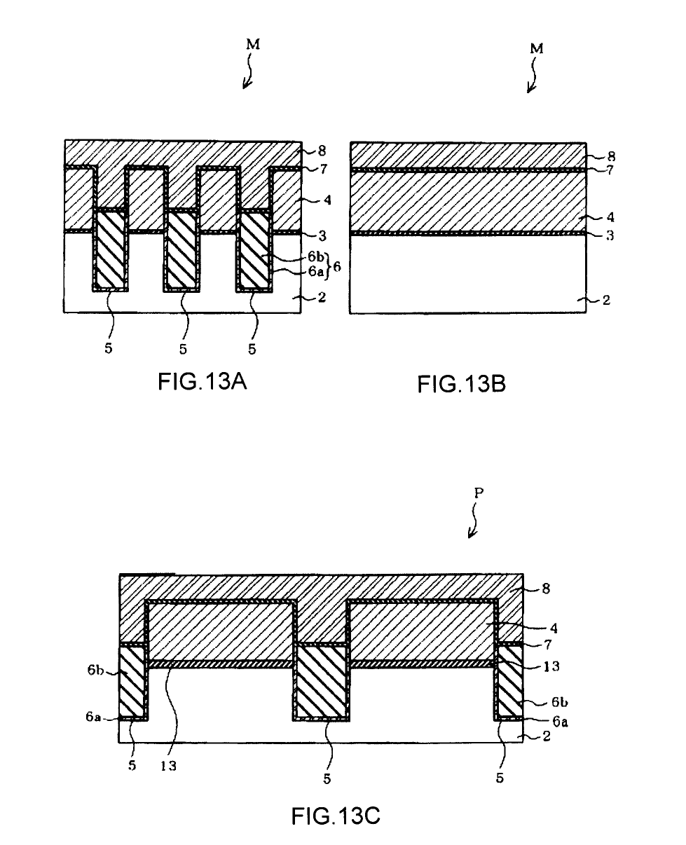

Subsequently, as shown in FIGS. 13A to 13C, polycrystalline silicon doped with phosphorus (P) is deposited by the LP-CVD. Thus, a conductive film 8 is formed.

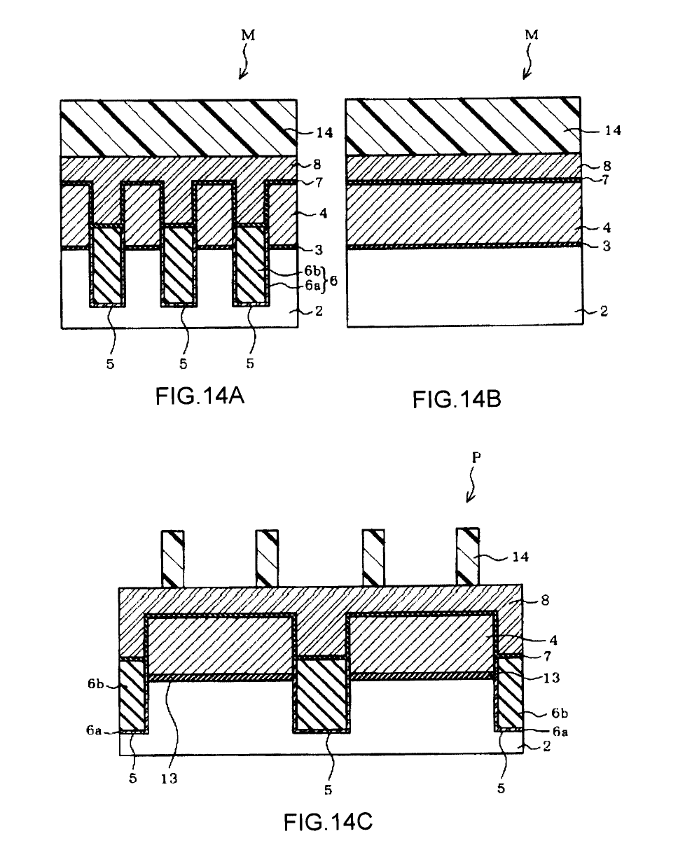

Subsequently, as shown in FIGS. 14A to 14C, photoresist 14 is applied and is then patterned to have a desired pattern. The patterning of the photoresist 14 is performed to form opening grooves K substantially at the center of the inter-gate insulator film 7 of the gate electrode PG in the peripheral area P. The photoresist 14 is patterned to have grooves at positions over the areas where the opening grooves K are to be formed. In addition, the patterning of the photoresist 14 is performed to remove the conductive film 8 at positions right above the oxide films 6a and 6b (i.e., element isolation areas BBa) in the peripheral area P. The photoresist existing on the conductive film 8 at the positions right above the element isolation areas BBa is removed at this step of patterning.

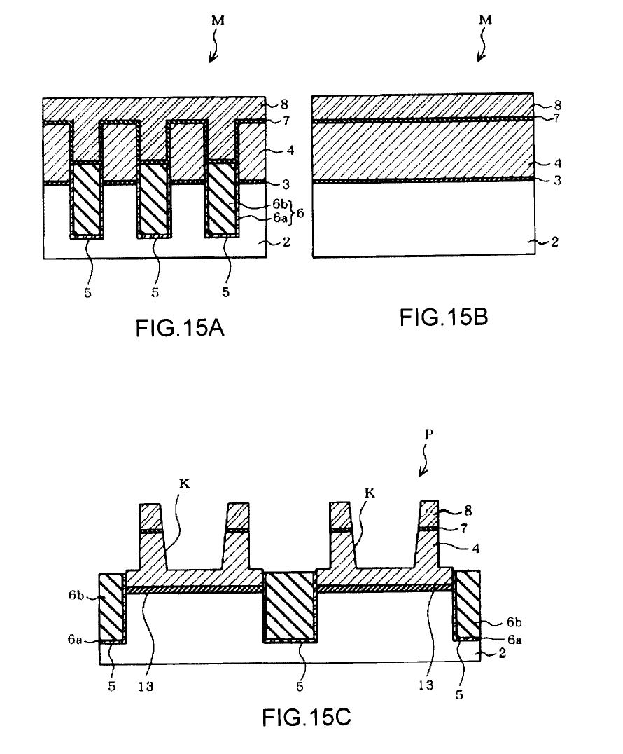

Subsequently, as shown in FIGS. 15A to 15C, by using the photoresist 14 as a mask, some parts of the conductive film 8, the inter-gate insulator film 7, and an upper portion (a part) of the conductive film 4 in the peripheral area P are removed by the RIE. As shown in FIG. 15C, the opening grooves K are formed through the conductive film 8 and the inter-gate insulator film 7 in the peripheral area P. At the same time, the inter-gate insulator film 7 and the conductive film 8 are removed simultaneously at positions above the oxide films 6a and 6b and at a side of the conductive film 4. After that, the photoresist 14 is removed by ashing.

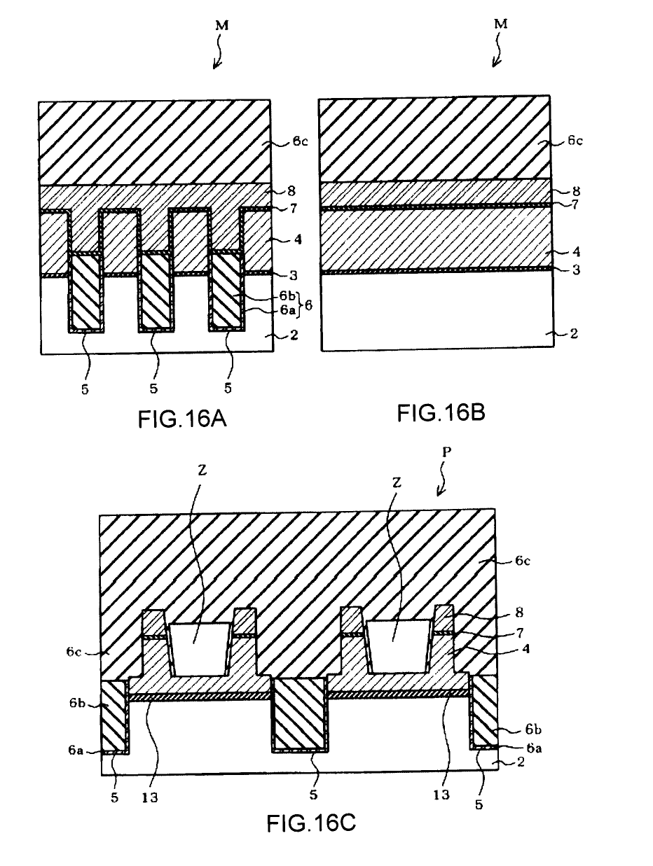

Subsequently, as shown in FIGS. 16A to 16C, an oxide film 6c (silicon oxide film) is deposited by the plasma CVD. During the deposition process, the oxide film 6c enters the opening grooves K formed through the conductive film 8 and the inter-gate insulator film 7 and in the conductive film 4. Thus, the oxide film 6c adheres to the internal surfaces of the opening grooves K defined by the conductive film 8, the inter-gate insulator film 7, and the conductive film 4. The oxide film 6c in each opening groove K is thinly formed, so that a void Z is left on the inner side of the oxide film 6c.

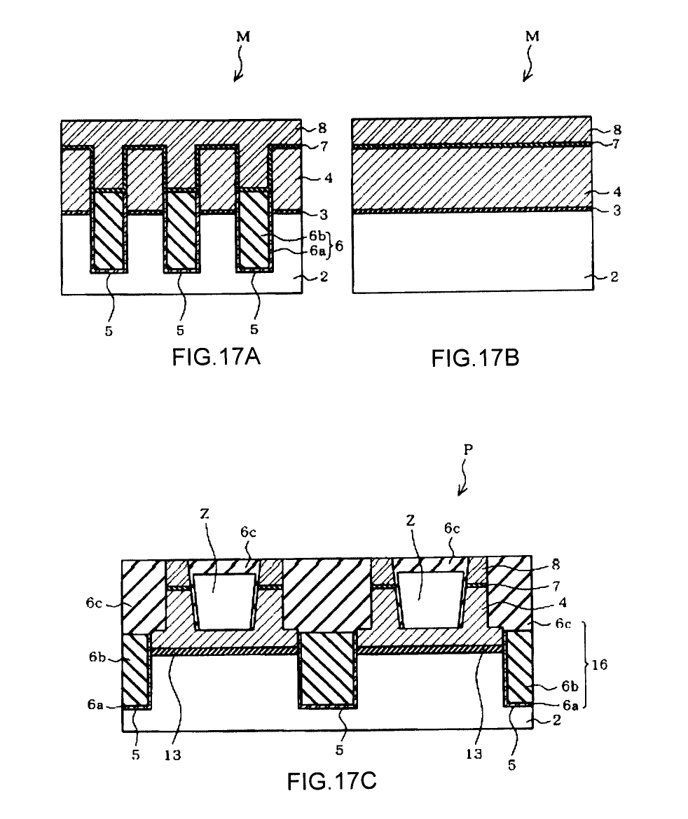

Subsequently, as shown in FIGS. 17A to 17C, the oxide film 6c is flattened by the CMP using the conductive film 8 as a stopper until the top surface of the conductive film 8 is exposed out. At this point, the peripheral area P, the oxide film 6c remains on the oxide films 6a and 6b in the peripheral area P, but the oxide film 6c on the conductive film 8 is entirely removed in the memory cell area M.

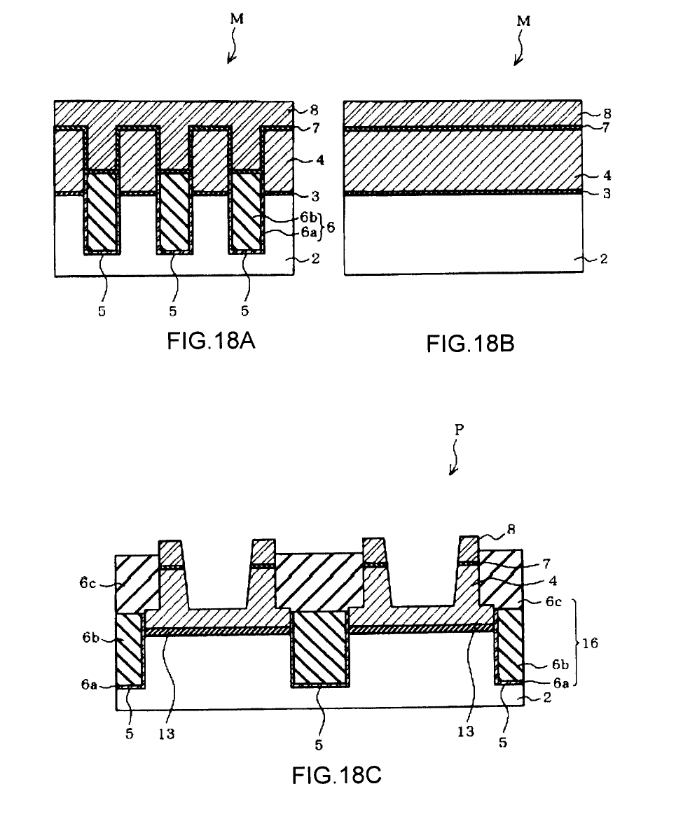

Subsequently, as shown in FIGS. 18A to 18C, a wet etching process is performed to remove the oxide film 6c deposited on and adhering to the internal surfaces of the opening grooves K. Here, an upper portion of the oxide film 6c deposited on the oxide films 6a and 6b are removed by a little amount.

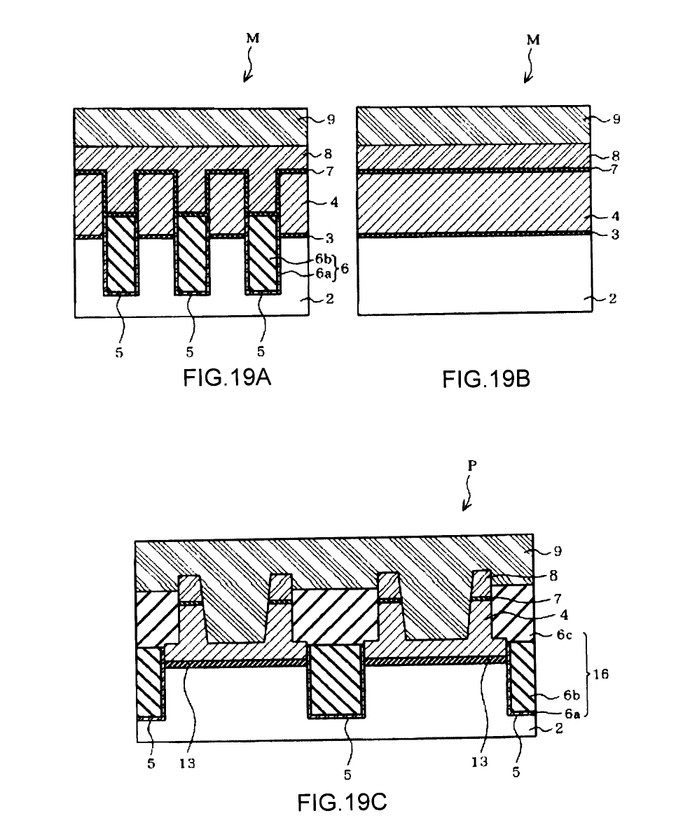

Subsequently, as shown in FIGS. 19A to 19C, polycrystalline silicon doped with phosphorus is deposited by the LP-CVD. Then, as shown especially in FIGS. 3B and 4B among FIGS. 3A, 3B, 4A, and 4B, a lithography process and an anisotropic etching process are performed to divide the layered films (4, and 7 to 9). If the etching process is performed under the etching conditions of non-high selectivity between the conductive films (4, 8, and 9) and the oxide film 6c, the oxide film 6c is removed as shown in FIG. 4B. If, in contrast, the etching process is performed under the etching conditions of high selectivity between the conductive films (4, 8, and 9) and the oxide film 6c, the oxide film 6c can remain.

Subsequently, an ion implantation process is performed to shallowly introduce impurities such as phosphorus at positions between stacked films (4 and 7 to 9) in the memory cell area M and at positions on the sides of each gate electrode PG in the peripheral area P. The regions doped with the impurities will be later subjected to a heat treatment to be impurity-diffused regions 2a serving as the source/drain regions. After interlayer insulation film (not illustrated) is deposited at positions between the stacked films (4, and 7 to 9), an upper portion of the silicon that forms the conductive film 9 is silicided to form the conductive film 10. Depending on metal materials used in the silicidation process of the conductive film 10, the layered film (4 and 7 to 10) may be divided after the fourth conductive film 10 made of the metal silicide is formed on each column of the layered film (4, and 7 to 9). To put it differently, the order of the steps may be changed.

After that, various kinds of interlayer insulation films, impurity-diffused regions 2b, bit line contacts CB, source line contacts, multilayer wiring structures are formed, and thus the NAND-type flash memory device 1 can be completed.

In summary, the manufacturing method of a NAND-type flash memory device according to this embodiment includes the following characteristic manufacturing steps. In the memory cell area M of the semiconductor substrate 2, the conductive film 4 for the floating gate electrodes FG is formed over the semiconductor substrate 2 with the first gate insulator film formed in between. In the meanwhile, in the peripheral area P, the conductive film 4 is formed over the semiconductor substrate 2 with the second gate insulator film 13 formed in between. Then, the element isolation trenches 5 are formed through the conductive film 4, and the gate insulation films 3 and 13, and into an upper portion of semiconductor substrate 2. The oxide film 6b is formed in the element isolation trenches 5. Both in the memory cell area M and in the peripheral area P, the inter-gate insulator film 7 is formed on the oxide film 6b and the conductive film 4. Subsequently, the conductive film 8 for the control gate electrodes CG is formed on the inter-gate insulator film 7.

Subsequently, in the peripheral area P, openings are formed through the conductive film 8 and the inter-gate insulator film 7 while the conductive film 8 and the inter-gate insulator film 7 formed on and over the oxide films 6b included in the second element isolation insulation layers 16 are removed. Simultaneously, the conductive film 4 is partially removed.

Subsequently, the oxide film 6c is formed at regions where the conductive film 8 is removed. Simultaneously, the oxide film 6c is also formed on the internal surfaces of the inter-gate insulator film 7 exposed in each opening region. Subsequently, the oxide film 6c on the internal surfaces of the inter-gate insulator film 7 exposed in each opening region is removed. Subsequently, electrical connections among the conductive films (4, 8, and 9) are secured by forming conductive film 9 in the opening regions formed in the inter-gate insulator film 7.

Thus, no oxide film 6c remains on the internal surfaces of the inter-gate insulator film 7 exposed in the opening regions. Thereby, the occurrence of contact failures among the conductive films (4, 8, and 9) can be prevented. In addition, desirable characteristics can be given to the structure of the second element isolation insulation layers 16 in the peripheral area P.

### Other Embodiments

Various modifications and applications described below can be made. The invention is applicable not only to NAND-type flash memory devices but also to non-volatile semiconductor memory devices, such as NOR-type flash memory devices, including a memory cell area and a peripheral circuit area.

A dummy transistor may be provided between the select gate transistor STS and the cell transistor MT, or between the select gate transistor STD and the cell transistor MT.

In the embodiments described above, the oxide film 6b is made of polysilazane. It is, however, allowable that the oxide film is formed by using other SOG (spin on glass) films, or by using films formed by the selective growth technique. If an oxide film formed by the selective growth technique is used as the oxide film 6b, the oxide film 6a does not have to be formed.

The opening groove K may have any form as long as the opening groove K allows the contact between the conductive films 4 and 9.

Some embodiments of the invention have been described thus far, but the invention is not limited to the configurations nor various conditions described in the embodiment. The embodiments are described as examples and do not intend to limit the scope of the invention. Those novel embodiments may be carried out in various other forms. Various omissions, replacements, and changes may be made without departing the gist of the invention. These embodiments and their modifications are included in the scope of and the gist of the invention, and are included also in the invention described in the claims and its equivalents.

What is claimed is:

1. A non-volatile semiconductor memory device comprising:
a memory cell area including
cell transistors each having
a first gate electrode formed on a semiconductor substrate with a first gate insulator film formed in between, and
a second gate electrode formed on the first gate electrode with an inter-gate insulator film formed in between, and
first element isolation insulation layers each embedded in a first element isolation trench in a way to electrically isolate the cell transistors from each other, and
a peripheral area including
high voltage transistors each having a third gate electrode including
a first conductor film formed on the semiconductor substrate with a second gate insulator film formed in between, and
a second conductor film being formed on the first conductor film and being in contact with the first conductor film via an opening formed in the inter-gate insulator film, and
second element isolation insulation layers each embedded in a second element isolation trench in a way to electrically isolate the high voltage transistors from each other, wherein
the first element isolation insulation layer in the memory cell area is formed by burying a first oxide film in the first element isolation trench, and the first oxide film has a top surface positioned at a level between a top surface of the semiconductor substrate and a top surface of the first gate electrode, and
the second element isolation insulation layer in the peripheral area includes the first oxide film having a top surface positioned at a higher level than the top surface of the semiconductor substrate, and a second oxide film formed on the first oxide film and having a top surface located at a higher level than a top surface of the first conductor film.

2. The non-volatile semiconductor memory device according to claim 1, wherein the second oxide film is not formed in the memory cell area, but is formed on the first oxide film of the second element isolation trench in the peripheral area.

3. The non-volatile semiconductor memory device according to claim 1, further comprising third oxide films formed along internal surfaces of the first element isolation trench and along internal surfaces of the second element isolation trench.

4. The non-volatile semiconductor memory device according to claim 2, further comprising third oxide films formed along internal surfaces of the first element isolation trench and along internal surfaces of the second element isolation trench.

5. The non-volatile semiconductor memory device according to claim 3, wherein
the first oxide film is made of polysilazane, and is formed inside the third oxide films formed along internal surfaces of the first element isolation trench in the memory cell area and along internal surfaces of the second element isolation trench in the peripheral area.

6. The non-volatile semiconductor memory device according to claim 3, wherein the third oxide films is made of an HTO film.

7. The non-volatile semiconductor memory device according to claim 4, wherein
the first oxide film is made of polysilazane, and is formed inside the third oxide films formed along internal surfaces of the first element isolation trench in the memory cell area and along internal surfaces of the second element isolation trench in the peripheral area.

8. The non-volatile semiconductor memory device according to claim 5, wherein the third oxide film is made of an HTO film.

9. The non-volatile semiconductor memory device according to claim 7, wherein the third oxide film is made of an HTO film.

10. A non-volatile semiconductor memory device comprising:
a semiconductor substrate having a memory cell area and a peripheral area;
cell transistors formed on the memory cell area, each having a first gate electrode formed on a semiconductor substrate with a first gate insulator film formed in between, and a second gate electrode formed on the first gate electrode with an inter-gate insulator film formed in between;
a first element isolation trench formed between the cell transistors;
a first element isolation insulation layer embedded in the first element isolation trench;
high voltage transistors formed on the peripheral area, each having a third gate electrode including a first conductor film formed on the semiconductor substrate with a second gate insulator film formed in between, and a second conductor film being formed on the first conductor film via the inter-gate insulator film and being in contact with the first conductor film through an opening groove formed in the inter-gate insulator film;
a second element isolation trench formed between the high voltage transistors; and
a second element isolation insulation layer embedded in the second element isolation trench, wherein
the first element isolation insulation layer includes a first oxide film, and the first oxide film has a top surface located at a level between a top surface of the semiconductor substrate and a top surface of the first gate electrode, and
the second element isolation insulation layer includes the first oxide film having a top surface located at a higher level than the top surface of the semiconductor substrate and a second oxide film formed on the first oxide film and having a top surface located at a higher level than a top surface of the first conductor film.

11. The non-volatile semiconductor memory device according to claim 10, wherein the second oxide film is not formed in the memory cell area, but is formed on the first oxide film of the second element isolation trench in the peripheral area.

12. The non-volatile semiconductor memory device according to claim 10, further comprising third oxide films formed along internal surfaces of the first element isolation trench and along internal surfaces of the second element isolation trench.

13. The non-volatile semiconductor memory device according to claim 11, further comprising third oxide films formed along internal surfaces of the first element isolation trench and along internal surfaces of the second element isolation trench.

14. The non-volatile semiconductor memory device according to claim 12, wherein
the first oxide film is made of polysilazane, and is formed inside the third oxide films formed along internal surfaces of the first element isolation trench in the memory cell area and along internal surfaces of the second element isolation trench in the peripheral area.

15. The non-volatile semiconductor memory device according to claim 12, wherein the third oxide films is made of an HTO film.

16. A manufacturing method of a non-volatile semiconductor memory device comprising the steps of:
forming a first conductor film for floating gate electrodes in a memory cell area of a semiconductor substrate with a first gate insulator film formed in between, and forming the first conductor film in a peripheral area of the semiconductor substrate with a second gate insulator film formed in between;
forming element isolation trenches in the first conductor film, the first gate insulator film, the second gate insulator film, and an upper portion of the semiconductor substrate;
forming a first oxide film in each of the element isolation trenches;
forming an inter-gate insulator film on the first oxide film and the first conductor film both in the memory cell area and in the peripheral area;
forming a second conductor film for control gate electrodes on the inter-gate insulator film;
in the peripheral area, forming opening grooves in the second conductor film, the inter-gate insulator film, and the first conductor film, and removing the second conductor film, the inter-gate insulator film, and a part of the first conductor film formed on top of the first oxide film;
forming a second oxide film in a region in the peripheral area where the second conductor film is removed;
removing the second oxide film formed on internal surfaces of an opening region of the inter-gate insulator film in the peripheral area; and
forming a third conductor film through the opening region of the inter-gate insulator film in the peripheral area, and thereby electrically connecting the first conductor film and the second conductor film to each other.

17. The manufacturing method of a non-volatile semiconductor memory device according to claim 16, further comprising a step of forming third oxide films along internal surfaces of the element isolation trench formed in the memory cell area and along internal surfaces of the element isolation trench formed in the peripheral area.

18. The non-volatile semiconductor memory device according to claim 17, wherein
the first oxide film is made of polysilazane, and is formed inside the third oxide films formed along internal surfaces of the element isolation trench in the memory cell area and along internal surfaces of the element isolation trench in the peripheral area.

19. The non-volatile semiconductor memory device according to claim 18 wherein the third oxide films is made of an HTO film.
